(19) United States
(12) Patent Application Publication
(10) Pub. No.: US 2006/0260787 A1
(43) Pub. Date: Nov. 23, 2006

(54) Flattened contact cooling module

(75) Inventors: Chung Wu, Taipei (TW); I-Yung Lin, Taipei (TW)

Correspondence Address: HDSL, 4331 STEVENS BATTLE LANE, FAIRFAX, VA, 22033, US

(73) Assignee: Chaun-Choung Technology Corp.

(21) Appl. No.: 11/134,340

(22) Filed: May 23, 2005

(51) Int. Cl. H05K 7/20

(52) U.S. Cl. 165/104.33; 361/700

(57) ABSTRACT

A flattened contact cooling module for cooling an electronic element. The cooling module has a reduced height (thickness), such that the overall thickness of an electronic product is reduced. The cooling module includes a heat conducting plate having a sagged portion, an elastic member disposed on the heat conducting plate, and a first cooling device disposed on the sagged portion. The heat conducting plate is adhered to the electronic element, so as to effectively dissipate heat generated therefrom.

### BACKGROUND OF THE INVENTION

The present invention relates generally to a contact cooling module, and more particularly to a flattened contact cooling module that has a reduced height (thickness) so as to reduce the occupation space of the cooling module in an electronic product.

The thumb rule of modem technology is to develop lighter, thinner, shorter and smaller electronic products. Thus, the user can easily carry and store the electronic products.

Such lighter, thinner, shorter and smaller electronic products are made of lighter, thinner, shorter and smaller component parts. In addition, it is often necessary to install cooling devices on such electronic products so as to dissipate the heat generated from the component parts, thereby assuring the normal operation of the electronic products.

However, the installation of cooling devices often requires the electronic product to have a larger thickness. As shown in FIG. 1 and FIG. 2, the heat conducting plate 101 of the cooling device 10 is adhered to the surface of an electronic device 102. A heat pipe 103 is further adhered to the surface of the heat conducting plate 101. An elastic member 104 is imposed on the surface of the heat pipe 103 and the heat conducting plate 101. The elastic member 104 is then affixed with the circuit board 105, so as to securely fasten the heat pipe 103 and the heat conducting plate 101 to the surface of the electronic device 102. The heat generated from the electronic device 102 during its normal operation is thus conducted to the heat conducting plate 101, to the heat pipe 103, and then to the cooling fins 106.

However, the heat conducting plate 101, the heat pipe 103 and the elastic member 104 of the cooling device described above form a certain thickness after they are being assembled. In order to fit the cooling device into an electronic product, more space is needed in the electronic product, thereby increasing the thickness of the electronic product. For this reason, it is difficult for electronic products to become lighter, thinner, shorter and smaller.

### SUMMARY OF THE INVENTION

The present invention is to provide a flattened contact cooling module that has a reduced height (thickness), such that the overall thickness of an electronic product is reduced.

In order to achieve the above and other objectives, the cooling module includes a heat conducting plate having a sagged portion, an elastic member disposed on the heat conducting plate, and a first cooling device disposed on the sagged portion. The heat conducting plate is adhered to the electronic element, so as to effectively dissipate heat generated therefrom.

### BRIEF DESCRIPTION OF THE DRAWINGS

FIG. 1 illustrates a conventional cooling device.

FIG. 2 is a sectional view of the conventional cooling device.

FIG. 3 is an explosive view of a cooling module of the present invention.

FIG. 4 is a perspective view of the cooling module of the present invention.

FIG. 5 is a sectional view of the cooling module of the present invention.

FIG. 6 is an explosive view of a cooling module, in accordance with another embodiment of the present invention.

FIG. 7 is a perspective view of the cooling module of FIG. 6.

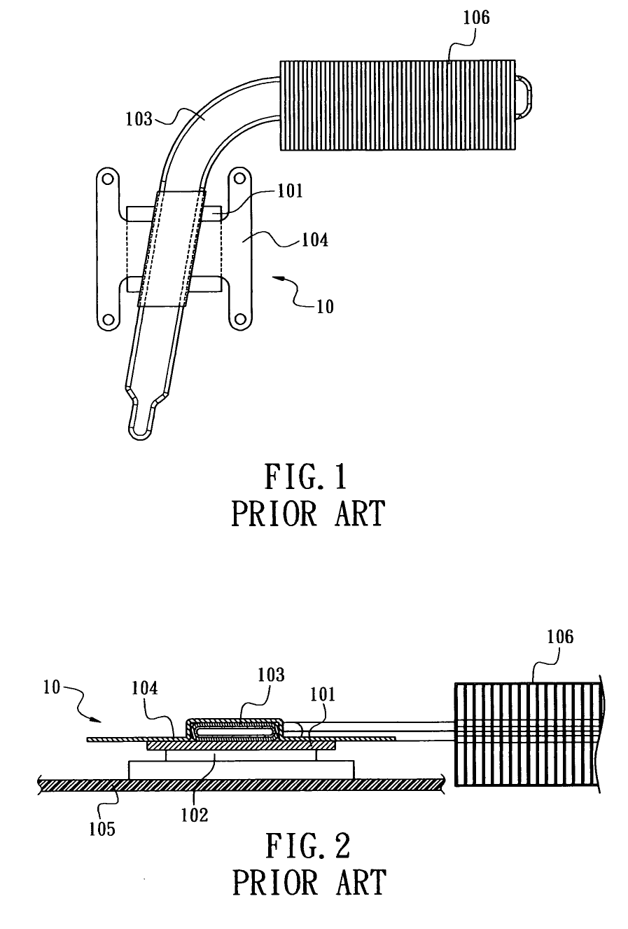

### DETAILED DESCRIPTION OF THE INVENTION

In order to better understanding the features and technical contents of the present invention, the present invention is hereinafter described in detail by incorporating with the accompanying drawings. However, the accompanying drawings are only for the convenience of illustration and description, no limitation is intended thereto.

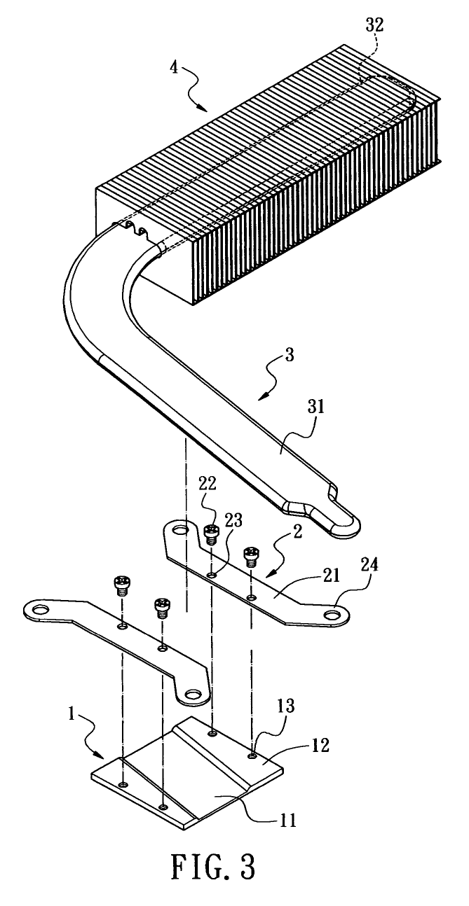

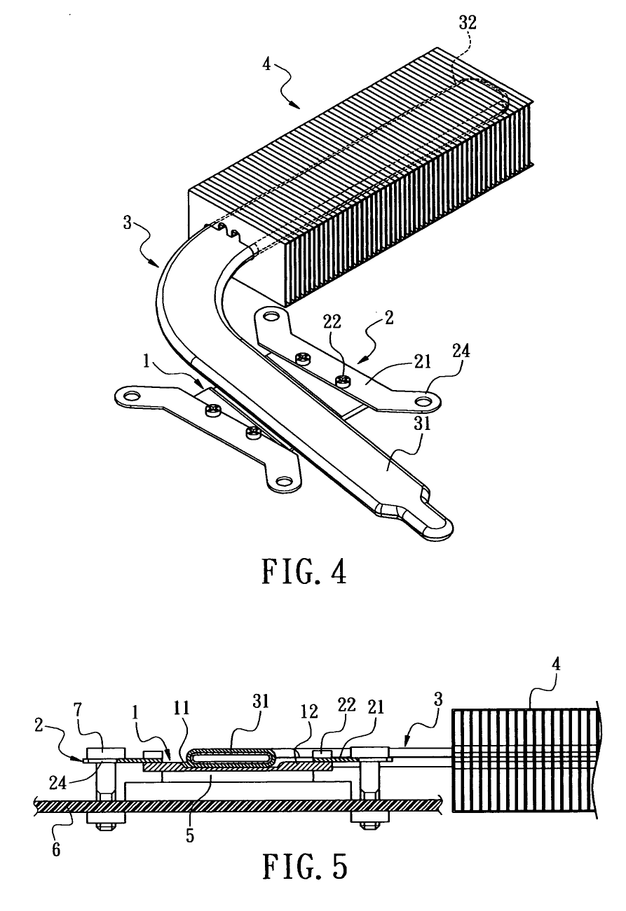

Referring to FIG. 3 and FIG. 4, an explosive view and a perspective view of a cooling module of the present invention are illustrated. As shown, the fattened contact cooling module includes a heat conducting plate 1, an elastic member 2, a first cooling element 3 and a second cooling element 4. The heat conducting plate 1, the elastic member 2 and the first cooling element 3 are assembled with each other so as to reduce the height of the cooling module, thus reducing the required available space of a computer main frame or a laptop computer.

The heat conducting plate 1 described above are made of heat conducting metallic materials, which includes a sagged portion 1. Two sides of the sagged portion 11 includes a connection hole 13 formed on a protrusive portion 12 thereof.

The elastic member 2 includes a connection portion 21 pressed on the protrusive portion 12 described above. The connection portion 21 includes a hole 23 for penetrating therethrough a fastening element 22, e.g. a screw. Two ends of the connection portion 21 includes an elastic portion 24 extensively formed thereon. The elastic portion 24 is fastened to a fastening structure of a circuit board (not shown), thereby allowing the elastic member 2 to securely be pressed on the heat conducting plate 1.

The first cooling element 3 is composed of a flattened heat pipe. The heat reception end 31 of the first cooling element 3 is assembled to the sagged portion 11 of the heat conducting plate 1 through the opening 21 of the elastic member 2. The heat absorbed by the heat conducting plate 1 is then conducted to the heat reception end 31. The heat is then conducted to the second cooling element 4 connected to the cooling end 32.

The second cooling element 4 is composed of a plurality of cooling fins, which can dissipate the heat from the cooling end 32 of the first cooling element 3.

Referring to FIG. 4 and FIG. 5, a perspective view and a sectional view of a cooling module of the present invention are illustrated. As shown, the fastening element 22 is first penetrated through the through hole 23 of the elastic member 2 and threaded with the connection hole 13 of the heat conducting plate 1, thereby assembling the elastic member 2 on the heat conducting plate 1.

The surface of the heat conducting plate 1 to be contacted with the electronic element 5, e.g. central processing unit, is coated with heat conducting material (not shown), and then adhered to the electronic element 5. The elastic portion 24 of the elastic member 2 is then fastened to the circuit board 6 via the fastening structure 7. The elastic member 2 is thus securely pressed on the heat conducting plate 1 and is adhered with the electronic element 5. The heat reception end 31 of the first cooling element is then disposed to the sagged portion 11 of the heat conducting plate 1. The heat generated from the operation of the electronic element 5 is then conducted to the heat conducting plate 1, and then to the heat reception end 31 of the first cooling device 3. Further, the heat is conducted to the cooling end 32 from the heat reception end 31, and dissipated through the second cooling element 4.

According to the assembly of the heat conducting plate 1, the elastic member 2 and the first cooling element 3 described above, the overall thickness has been significantly reduced. Therefore, the thickness of the computer main frame is also reduced accordingly.

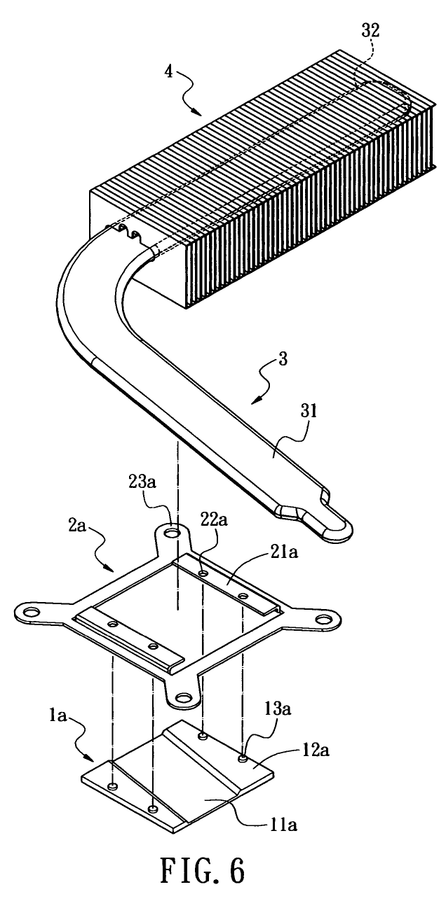

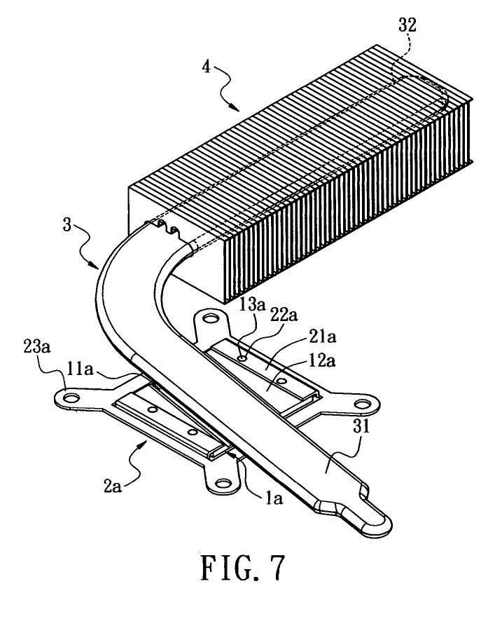

Referring to FIG. 6 and FIG. 7, an explosive view and a perspective view of another embodiment of the present invention are illustrated. As shown, the primary difference between this particular embodiment and the embodiment described above is in the heat conducting plate 1a and the elastic member 2a. The heat conducting plate 1a includes a sagged portion 11a, while the protrusive portions 12a formed on the two sides of the sagged portion 11a include a positioning point 13a.

The elastic member 2a includes a connection portion 21a connected to the protrusive potion 12a described above. The connection portion 21a includes a positioning hole 22a formed on the positioning point described above. The elastic member 2a includes a plurality of elastic portions 23a.

The conducting plate 1a is first assembled with the connection portion 21a of the elastic member 2a. After the surface of the heat conducting plate 1a to be contacted with the electronic element is coated with heat conducting materials, the heat conducting plate 1a is adhered to the electronic element. The elastic portion 23a of the elastic member 2a is fastened to the circuit board via the fastening structure. The elastic member 2a is thus securely pressed on the heat conducting plate 1a, and contacts the electronic element. The heat reception end 31 of the first cooling element 3 is then disposed to the sagged portion 11 of the heat conducting plate 1. The heat generated from the operation of the electronic element is then conducted to the heat conducting plate 1 and to the heat reception end 31 of the first cooling device 3. Further, the heat is conducted from the heat reception end 31 to the cooling end 32, and is dissipated through the second cooling element 4.

Moreover, the connection between the heat conducting plate 1 and the elastic member 2 is not limited to employing the fastening element, other connections means such as adhesion, soldering, embedding and nailing are also applicable.

Since, any person having ordinary skill in the art may readily find various equivalent alterations or modifications in light of the features as disclosed above, it is appreciated that the scope of the present invention is defined in the following claims. Therefore, all such equivalent alterations or modifications without departing from the subject matter as set forth in the following claims is considered within the spirit and scope of the present invention.

1. A flattened contact cooling module for cooling an electronic element, comprising:
a heat conducting plate disposed on the electronic element, the heat conducting plate comprising a sagged portion and a protrusive portion formed on each of two sides of the sagged portion; and
a pair of elastic members disposed merely on two protrusive portions of the heat conducting plate, respectively. Each elastic member comprising a connection portion connected to the protrusive portion, each of two ends of the connection portion connecting with an elastic portion to be fastened on the circuit board.

2. The flattened contact cooling module as recited in claim 1, wherein the heat conducting plate is made of heat conducting metallic materials.

3. The flattened contact cooling module as recited in claim 1, wherein the protrusive portion comprises a connection hole, the connection portion comprises a through hole, and a fastening element penetrates through the through hole to connect with the connection hole.

4. (canceled)

5. (canceled)

6. The flattened contact cooling module as recited in claim 4, wherein the heat conducting plate is fastened to the elastic member via adhesion, soldering, embedding, or nailing.

7. A flattened contact cooling module for cooling an electronic element on a circuit board, comprising:
a heat conducting plate disposed on the electronic element, the heat conducting plate comprising a sagged portion and a protrusive portion formed on each of two sides of the sagged portion;
a pair of elastic members disposed merely on two protrusive portions of the heat conducting plate, respectively, each elastic member comprising a connection portion connected to the protrusive portion, each of two ends of the connection portion connecting with an elastic portion to be fastened on the circuit board; and
a first cooling element disposed on the sagged portion.

8. The flattened contact cooling module as recited in claim 7, wherein the first cooling element comprises a flattened heat pipe including a heat reception end and a cooling end.

9. The flattened contact cooling module as recited in claim 7, wherein one end of the first cooling device connected to a second cooling device composed of a plurality of cooling fins.

10. A flattened contact cooling module for cooling an electronic element, comprising:
a heat conducting plate disposed on the electronic element, the heat conducting plate rising a sagged portion, two sides of the sagged portion having a protrusive portion, the protrusive portion including a positioning point;
an elastic member disposed on the heat conducting plate, the elastic member comprising a connection portion connected to the protrusive portion, the connection portion including a connection hole connected to the positioning point.
